(19) United States
(12) Patent Application Publication
(10) Pub. No.: US 2012/0001273 A1
(43) Pub. Date: Jan. 5, 2012

(54) Micro-package for Micromachining Liquid Flow Sensor Chip

(75) Inventors: Chih-Chang Chen, Cupertino, CA (US); Liji Huang, San Jose, CA (US)

(73) Assignee: Siargo Ltd., Santa Clara, CA (US)

(21) Appl. No.: 12/830,237

(22) Filed: Jul. 2, 2010

(51) Int. Cl. H01L 29/66

(52) U.S. Cl. 257/414; 257/E29.166

(57) ABSTRACT

The current invention disclosed a micro-package design for packaging of micromachining liquid flow sensor. The package in present invention is fabricated with micromachining or micro-molding approach, which can greatly reduce the manufacturing cost due to the batch production. The micro-package design provides packaging solution for general micromachining liquid flow sensors that can enable various microfluidic applications while reaching the cost threshold for a disposable unit.

### BACKGROUND OF THE INVENTION

A microfabricated package design for micromachined silicon liquid flow sensor and its manufacturing method are disclosed in present invention. Measurement of liquid flow rate in a microfluidic configuration is often a great challenge as the technique is limited by the volumetric flow channel which is very slow in response and bulky with uncertain errors. Coriolis flow meter is one of the most prevailed technologies in this scope. However, Coriolis flow meter is unmerited by its bulky and costly characteristics since which generally requires complicated calibrations whereas it is difficult for mass production. Another alternative technology is to measure differential pressure to derive the flow rate like Pitot tube. This technology nonetheless is practically limited by its drawback of inaccuracy. As the current mechanical infusion pumps do not have any controls in dosing speed and the prevention of embolism is difficult to realize, development of a sensor for the purpose would be very valuable. In addition, one of the most important issues in homecare medication would be the minimization of contamination in addition to the cost as the users may not have enough trainings or knowledge for the applications. Therefore the disposable capability would be very critical. There are a quite few efforts for attacking the existing problems. Existing technology such as optical or ultrasonic can theoretically identify the air embolism problems while providing the measurement of the flow rate. The cost and bulky packages however make them impossible for the disposable applications.

Disposal types of liquid flow sensors in many home care medical apparatus have been required to avoid cross contamination. Mayer et al. (U.S. Pat. No. 6,813,944) teaches a MEMS thermal mass flow sensor for such purpose. The sensor is however placed outside of sidewall of a highly thermal conductive micro-tube, such that the fluid flow can still be sensed with a higher power operation. But this approach suffers high cost issues due to its sensor packaging while a long term drift is often occurring. Current medical applications requirement for disposable units in dosing, infusion pump and smart injection all require a more accurate measurement of medical grade liquid medication in a micro channel. One of the home care medical devices such as infusion pump have comprised a micromachining liquid flow sensor to handle the micro flow during medicine injection so that a constant injection rate can be preserved for accurate dosage and optimum effects of injected medicine. The threshold of feasibility for disposal type of liquid flow senor will significantly rely on the cost structure of sensor packaging. It would therefore be especially desirable to develop a low-cost and reliable micro-package structure which could be applied in various applications of microfluidics.

### SUMMARY OF THE INVENTION

The invention is to utilize medical grade or medical compatible materials to form a seamless fluid channel where micromachining silicon thermal liquid flow sensors can be packaged on such that the medical or biomedical fluid can pass through without residues. Specifically it can be applied to any applications requiring measurement of fluid flow in a micro channel with a stringent hygienic requirement. The micromachining silicon flow sensor comprises freestanding membranes, cavities, and/or multi-layered structures. This invention effectively provides an ultra disposable solution that is very cost effective for mass production of the liquid mass flow technology. The micro-package in current invention can be manufactured using a standard micromachining of etching or micro molding process; thereof it provides easy manufacturability and can significantly reduce the cost. In the current invention, we present the design and prototype of such micro-package. A micromachining silicon thermal liquid flow sensor chip with calorimetric principle is separated from the control electronics and encapsulated into this micro-package where a pre-manufactured micro-fluidic channel provide the path for the medicine with the sensor placed at the wall of the channel. This object is reached by the embodiments of claims.

BRIEF DESCRIPTIONS OF THE DRAWINGS

The present invention will be more fully and completely understood from a reading of the Description of the Preferred Embodiment in conjunction with the drawings, in which:

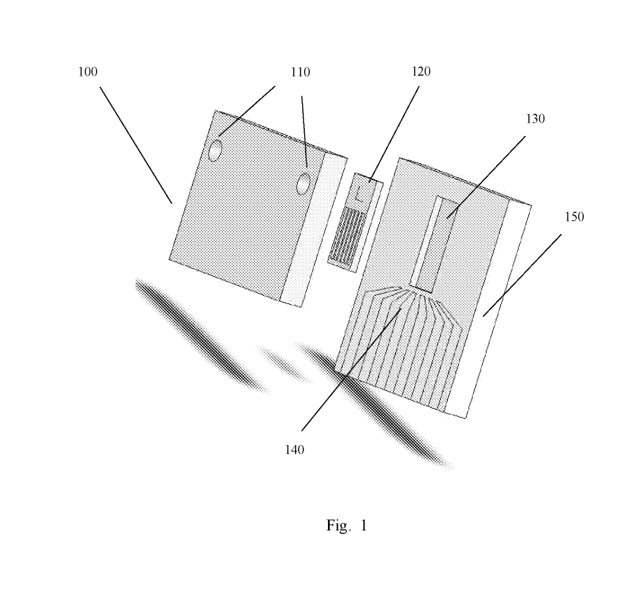

FIG. 1—is an exploded view of assembled package of first embodiment.

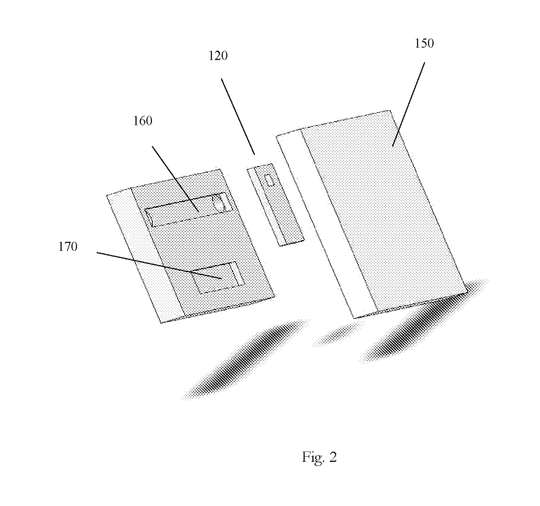

FIG. 2—is an exploded view of assembled package of first embodiment by different view angle.

FIG. 3—is a prospective view illustrating the assembled package of first embodiment.

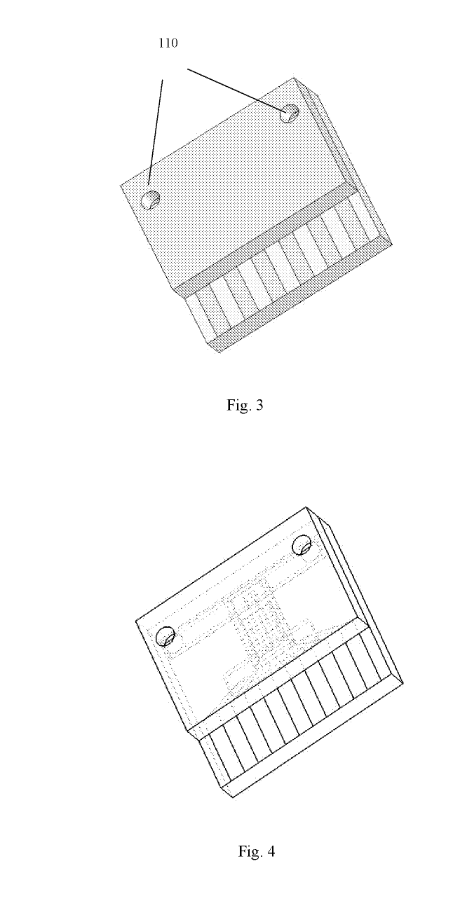

FIG. 4—is a prospective view illustrating the assembled package with hidden lines of first embodiment.

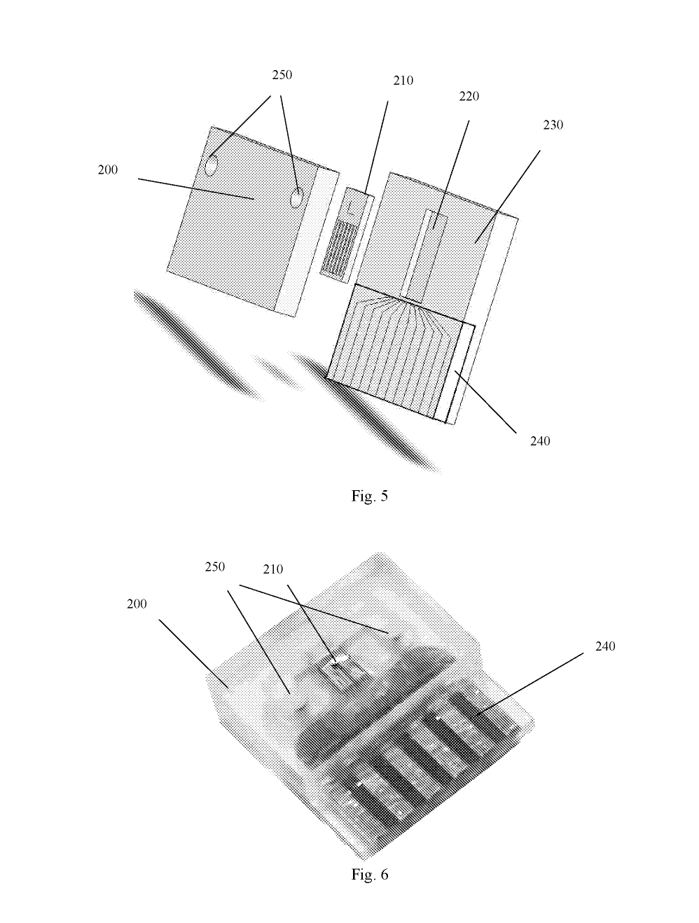

FIG. 5—is an exploded view illustrating the assembled package of second embodiment.

FIG. 6—is a picture of the prototype of second embodiment of present invention.

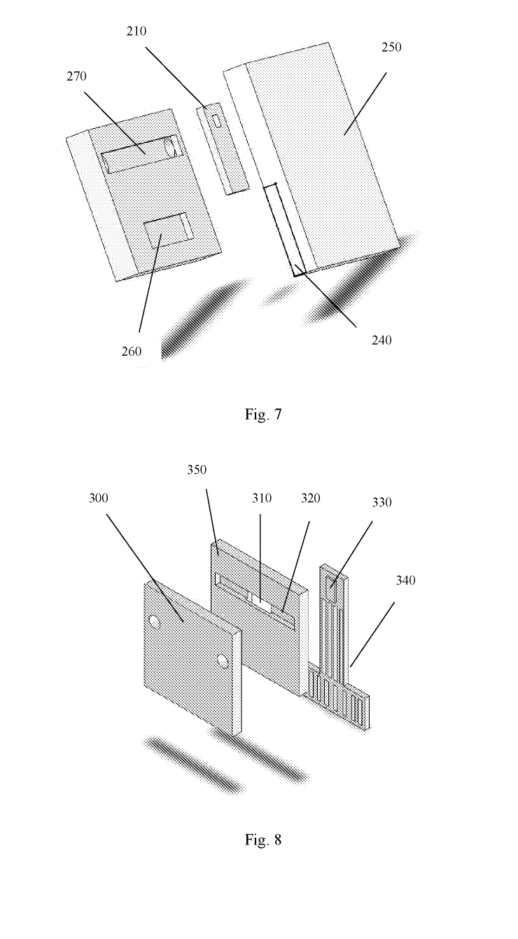

FIG. 7—is an exploded view illustrating the assembled micro-package of second embodiment by different view angle.

FIG. 8—is an exploded view illustrating the assembled package of third embodiment.

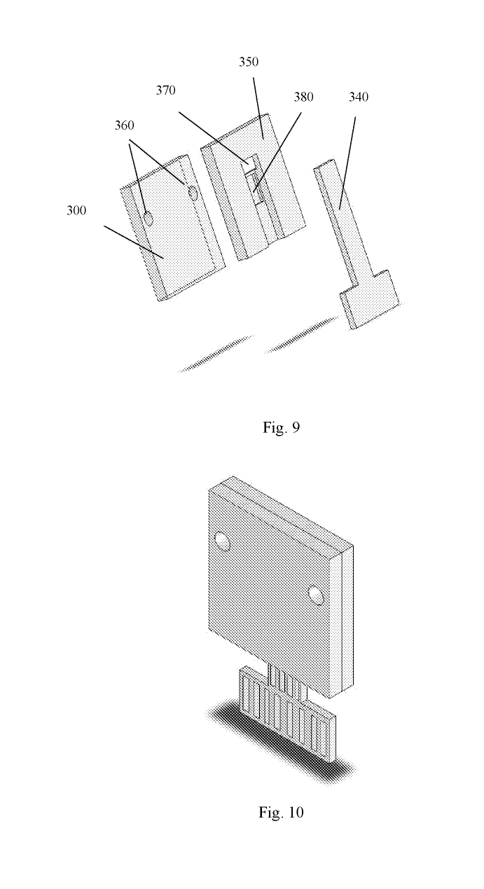

FIG. 9—is an exploded view illustrating the assembled package with hidden lines of third embodiment by different view angle.

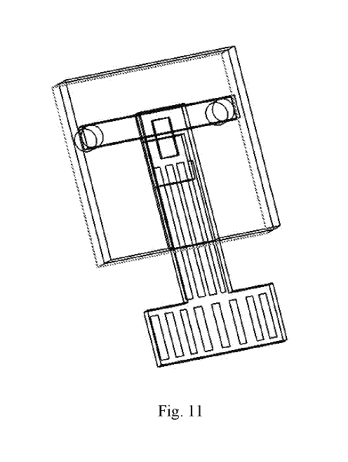

FIG. 10—is a prospective view illustrating the assembled package of third embodiments.

FIG. 11—is a prospective view illustrating the assembled package with hidden lines of third embodiment.

### DETAILED DESCRIPTION OF THE PREFERRED EMBODIMENTS

The measurable flow range for the micromachining thermal mass flow sensor is determined by the design of the flow sensor and the flow channel size. It is also important for the package design that the manufacture cost must be taken into accounts for its disposable requirement. FIG. 1 shows a concise package design and the prototyped sensor picture. The package has a dimension about 10×12 mm containing three components 100, 120, 150. The flow channel 160 and inlet/outlet ports (110) are made on component 100 where the rectangular flow channel dimension was designed to be 1.2×2.8 mm to meet the flow range requirements. Component 120 is the liquid flow sensor that would be placed into the cavity (130) shown in the sensor holder (150). The liquid flow sensor will be wire bonded to the top ends of metal line 140 in sensor holder 150. The sensor holder (150) has sputtered or electroplated metal layers and pattered as interconnection (140) by photolithography and etching process. After wire bonding of the sensor (120) connecting to the sensor holder (150), component 100 is bonded with 150 either via an ultrasonic bonding or by medical compatible glue. There is a recess cavity 170 which is a housing kept for bonding wires to avoid their damage after the package is assembled. The package is then ready to be connected with control electronic circuits as shown in FIG. 3.

Second embodiment of present invention is demonstrated in FIG. 5. Since the fabrication process for metal lines on component 230 is sometimes having high cost. A printed circuit board 240 having much low cost is introduced to provide the same function of interconnection as metal lines 140 shown in 150. The designed printed circuit board 240 is attached to component 230 as shown in FIG. 5. Many medical compatible plastic materials can be selected as component 200 and 230 depending on the specific applications. Among them, polycarbonate and polyphenylsulfone are commonly used and the final experimental prototype picture shown in FIG. 6 is fabricated by polyphenylsulfone. This package design of present invention pushes the cost to the lowest possible, and estimated in few tens of cents in volume, which turns the disposable medical sensor concept a reality.

Third embodiment of current invention is presented in FIGS. 8, 9 and 10. The micro-package comprised three major components: top cover 300, flow channel plate 340, and printed circuit board 340. The component 350 has an embedded flow channel 320 and an open window 310 to expose liquid flow sensor to flow media. The liquid flow sensor 330 is attached and wire bonded to printed circuit board 340. The PCB 340 is assembled into component 350 and then combined with component 300 to complete the package as shown in FIG. 10.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A micro-package for micromachining liquid flow sensor chip comprising:
a top component having an embedded flow channel and a trench cavity for wire-bonding wires; and
a bottom component having a trench cavity as a housing of said micromachining liquid flow sensor chip, which is with a dimension of said micromachining liquid flow sensor chip.

2. The micro-package for micromachining liquid flow sensor chip of claim 1 wherein
said bottom component of said micro-package has a metal lines pattern as wire bonding pads and signal input/output interconnection.

3. The micro-package for micromachining liquid flow sensor chip of claim 1 wherein
said top component of said micro-package has two open holes in each end of said embedded flow channel respectively as flow inlet and outlet of said embedded flow channel.

4. A micro-package for micromachining liquid flow sensor chip comprising:
a top component having an embedded flow channel and a trench cavity for wire-bonding wires; and
a bottom component having a trench cavity as a housing of said micromachining liquid flow sensor chip, which is with a dimension of said micromachining liquid flow sensor chip.

5. The micro-package for micromachining liquid flow sensor chip of claim 4 wherein
said bottom component of said micro-package has a recess on front surface which leaves a space to attach a separated printed circuit board with metal lines pattern for wire bonding and signal input/output interconnection.

6. The micro-package for micromachining liquid flow sensor chip of claim 4 wherein
said top component of said micro-package has two open holes in each end of said embedded flow channel respectively as flow inlet and outlet of said embedded flow channel.

7. A micro-package for micromachining liquid flow sensor chip comprising:
a top component as being a top cover of said micro-package;
a printed circuit board having said liquid flow sensor chip attached and wire-bonded to;
a bottom component of said micro-package having an embedded flow channel.

8. The micro-package for micromachining liquid flow sensor chip of claim 7 wherein
said printed circuit board has a metal lines pattern for wire bonding and signal input/output interconnection.

9. The micro-package for micromachining liquid flow sensor chip of claim 7 wherein
said bottom component of said micro-package has a recess space from bottom surface for assembling said printed circuit board.

10. The micro-package for micromachining liquid flow sensor chip of claim 7 wherein
top half of said liquid flow sensor chip on said printed circuit board is exposed to liquid flow through an opening on said recess space of said bottom component of said micro-package.

11. The micro-package for micromachining liquid flow sensor chip of claim 7 wherein
said top component of said micro-package has two open holes in each end of said embedded flow channel respectively as flow inlet and outlet of said embedded flow channel.
